(19) United States
(12) Patent Application Publication
(10) Pub. No.: US 2025/0356547 A1
(43) Pub. Date: Nov. 20, 2025

(54) SYSTEM AND METHOD FOR RECONSTRUCTING MR IMAGES FROM MULTIPLE SPARSE-SAMPLED SCANS

(71) Applicant: Aspect Imaging Ltd., Shoham (IL)

(72) Inventor: Gil Farkash, Shoham (IL)

(73) Assignee: Aspect Imaging Ltd., Shoham (IL)

(21) Appl. No.: 18/668,168

(22) Filed: May 18, 2024

(51) Int. Cl. G06T 11/00; G06T 3/40

(52) U.S. Cl. CPC G06T 11/006; G06T 3/40; G06T 2210/41; G06T 2211/441

(57) ABSTRACT

A first artificial intelligence (AI) engine receives a plurality of incomplete magnetic resonance (MR) K-space data matrices of an object scanned by an MR device. Each of the incomplete MR K-space data matrices comprises complex values and is the result of a corresponding san of the object by the MR device using a sparse-sampled MR scan acquisition sequence. Each sparse-sample MR scan acquisition sequence employs a unique sampling pattern. The first AI engine reconstructs a complete MR K-space data matrix of the scanned object, corresponding to a complete MR K-space acquisition. The reconstruction is based on the data in the plurality of incomplete MR K-space data matrices.

### BACKGROUND

The disclosure relates generally to magnetic resonance (MR) imaging, and more particularly to MR imaging using sparse-sampled acquisition schemes.

Sparse sampling is a common technique used to accelerate magnetic resonance imaging (MRI) acquisitions. While sparse sampling techniques reduce the number of acquired K-space lines (readouts) and can potentially reduce the MRI acquisition time, resultant MR image quality can suffer from a lack of spatial information. At the same time, MR images resultant from full or complete sampling of K-space can include ghosting and artifacts. Accordingly, a need exists for reconstructing an MR image using sparse-sampled scans resulting in improved image quality.

### BRIEF DESCRIPTION OF THE DRAWINGS

The accompanying drawings illustrate several embodiments, and together with the description, serve to explain the disclosed principles. One skilled in the relevant art will understand, however, that embodiments can be practiced without all of the specific details of the illustrated examples. Likewise, one skilled in the relevant art will also understand that the technology may include well-known structures or functions not specifically illustrated to avoid unnecessarily obscuring the relevant descriptions of the various examples. In the drawings:

FIG. 1 illustrates an exemplary method for reconstructing a complete MR K-space data matrix based on a plurality of incomplete MR K-space data matrices, in accordance with some embodiments of the disclosure.

FIG. 2 illustrates an exemplary method for training a first AI engine for the reconstruction illustrated in FIG. 1, in accordance with some embodiments of the disclosure.

FIG. 3 illustrates an exemplary workflow of using a first AI engine to reconstruct a complete MR K-space data matrix in accordance with some embodiments of the disclosure.

FIG. 4 illustrates a first exemplary workflow of training a first AI engine in accordance with some embodiments of the disclosure.

FIG. 5 illustrate a second exemplary workflow of training a first AI engine in accordance with some embodiments of the disclosure.

FIG. 6 illustrates a third exemplary workflow of training a first AI engine in accordance with some embodiments of the disclosure.

FIG. 7 illustrates an exemplary functional block diagram of a system including a first AI engine configured in accordance with embodiments of the disclosure.

### DETAILED DESCRIPTION

Several embodiments are discussed below in more detail in reference to the figures, where common numerals refer to the same method block, feature or component. Other embodiments in addition to those described herein are within the scope of the disclosure. Moreover, a person of ordinary skill in the art will understand that embodiments of the disclosure may have configurations, components, and/or procedures in addition to those shown or described herein and that these and other embodiments may be implemented without several of the configurations, components, and/or procedures shown or described herein without deviating from the disclosure. Reference throughout this description to “one embodiment,” “an embodiment,” “one or more embodiments,” an “nth embodiment,” or “some embodiments” means that a particular feature, support structure or characteristic described in connection with the embodiment is included in at least one embodiment of the present disclosure. Thus, use of such terminology is not necessarily referring to the same embodiment. For example, it is expressly contemplated that the features described herein may be combined in any suitable manner in one or more embodiments.

### Reconstruction Using an AI Engine

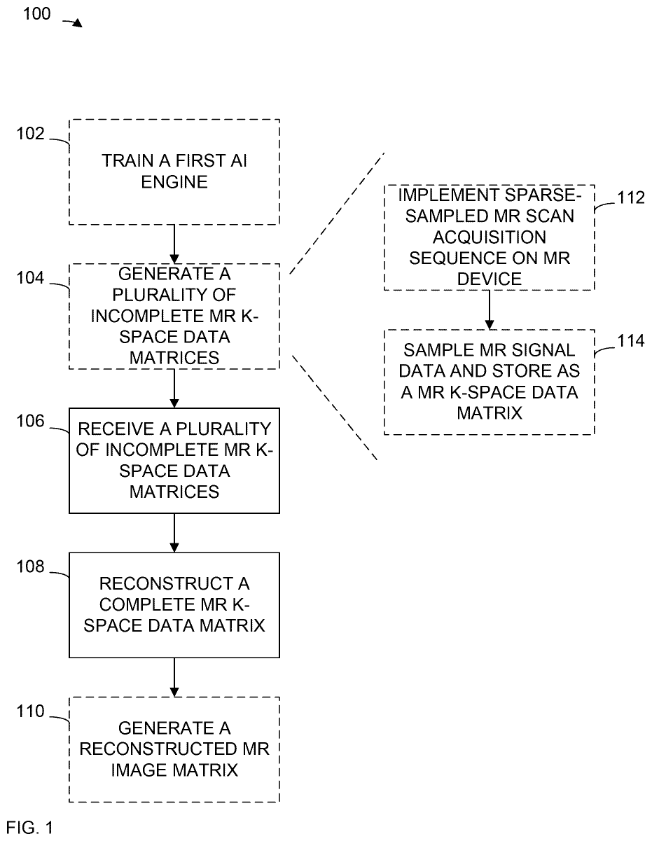

With reference to FIGS. 1, 3 and 7, an exemplary method 100, workflow 300 and system 700 for, among other things, reconstructing a complete magnetic resonance (MR) K-space data matrix based on a plurality of incomplete MR K-space data matrices is illustrated. Method 100 may include receiving a plurality of incomplete MR K-space data matrices at block 106. In one embodiment, the plurality of incomplete MR K-space data matrices may be received by a first artificially intelligence (AI) engine 310. First AI engine 310 may be a convolutional neural network based on a first deep learning model. Each incomplete MR K-space data matrix of the plurality of incomplete MR K-space data matrices may comprise complex values and may be the result of a scan of an object scanned by an MR device using a sparse-sampled MR scan acquisition sequence. In one embodiment, each of the incomplete MR-K space matrices of the plurality of incomplete MR K-space data matrices may be the result of a scan of an object scanned by an MR device obtained at the same position. For example, each of the incomplete MR-K space matrices may be the result of a scan of an object obtained at the same X-Y-Z position; i.e., the coordinates of the object (e.g., patient or body contours) have not changed across the scans, in each case relative to the magnetic field gradients imposed in X-Y-Z by the MR device gradient coils (not depicted).

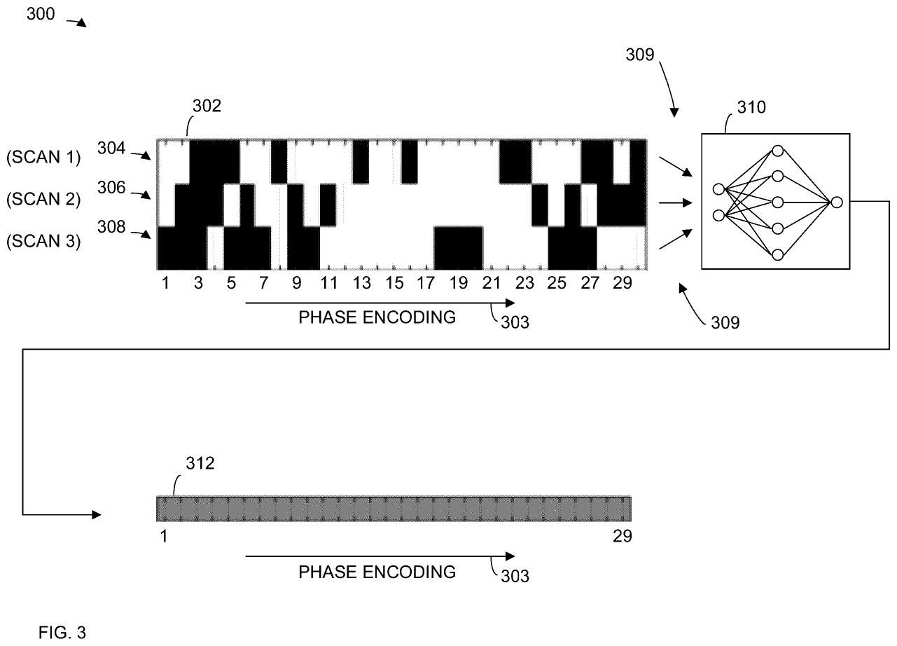

FIG. 3 depicts an exemplary plurality of incomplete MR K-space data matrices 302 received by first AI engine 310 as multi-channel inputs 309. In one embodiment, each sparse-sampled MR scan sequence uses or employs a unique sampling pattern. Exemplary plurality of incomplete MR K-space data matrices 302 includes a first incomplete MR K-space data matrix 304 associated with a first scan of an object using a sparse-sampled MR scan acquisition sequence, a second incomplete MR K-space data matrix 306 associated with a second scan of an object using a sparse-sampled MR scan acquisition sequence, and a third incomplete MR K-space data matrix 308 associated with a third scan of an object using a sparse-sampled MR scan acquisition sequence. In one embodiment, scans 1-3 of the same object and obtained at the same position. For example, each of scans 1-3 may be obtained at the same X-Y-Z position; i.e., the coordinates of the object have not changed across the scans, in each case relative to the magnetic field gradients imposed in X-Y-Z by the MR device gradient coils.

In one embodiment, each unique sampling pattern is unique across the phase-encoded dimension 303 of K-space, as is generally depicted in FIG. 3. Accordingly, the plurality of incomplete MR K-space data matrices 302 may contain variations in sampled spatial information due to one or more differences in the unique sampling patterns used to obtain such plurality of incomplete MR K-space data matrices 302. In one embodiment, each unique sampling pattern is a unique realization of the same probability distribution function. In some embodiments, the probability distribution function is a Gaussian probability function or a Poisson probability distribution function. Other functions may be employed.

In one embodiment, method 100 may optionally include generating the plurality of incomplete MR K-space data matrices 302 at block 104. Generation of the plurality of incomplete MR K-space data matrices 302 may include implementing a sparse-sampled MR scan acquisition sequence on an MR device at block 112, e.g., resulting in MR signal data at a receiver coil (not depicted) of the MR device 716. Generation of the plurality of incomplete MR K-space data matrices 302 may further include sampling the MR signal data and storing such data as a single MR K-space data matrix at block 114. Method blocks 112 and 114 may be repeated to generate one or more additional incomplete MR K-space data matrices that may collectively form the plurality of incomplete MR K-space data matrices 302. For T1-weighted MR imaging, the plurality of incomplete MR K-space data matrices 302 may include two incomplete MR K-space data matrices. For T2-weighted MR imaging, the plurality of incomplete MR K-space data matrices 302 may include two incomplete MR K-space data matrices. For diffusion-weighted MR imaging, the plurality of incomplete MR K-space data matrices 302 may include three incomplete MR K-space data matrices. The generation of the plurality of incomplete MR K-space data matrices 302 may be acquired using a static MR acquisition technique. Each of the plurality of incomplete MR K-space data matrices may be a two-dimensional MR K-space data matrix.

MR device 716 is an exemplary MR device that may be used to generate the plurality of incomplete K-space data matrices 302. As may be relevant to the generation of the plurality of incomplete MR K-space data matrices, MR device 716 may include an MR scanner 718, one or more sparse-sampled MR scan acquisition sequences 720, a plurality of unique sampling patterns 722, unique sampling pattern generator 724, sampler 726, and/or memory 728. The one or more sparse-sampled MR scan acquisition sequences 720 may be stored in memory (not otherwise depicted), e.g., as a bank.

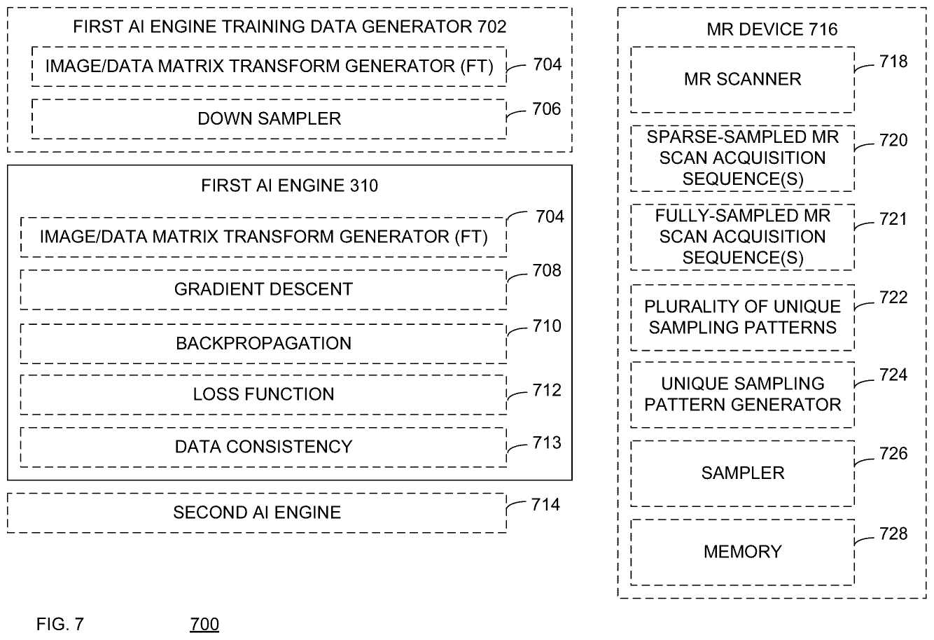

Method blocks 104 and 112 and 114 may be implemented using MR device 716 and in particular using MR scanner 718 implementing a sparse-sampled MR scan sequence 720, sampler 726, and memory 728. In some embodiments, blocks 104 and 112 may include selecting the unique sampling pattern for each sparse-sampled MR scan acquisition sequence. The selection may be random or semi-random. Returning to FIG. 7, MR Device 716 may include a unique sampling pattern generator 724 adapted to either select each unique sampling pattern, e.g., from a bank 722, or generate each such unique sampling pattern.

Method 100 may continue with block 108 where a complete MR K-space data matrix may be reconstructed. The reconstruction may be based on the data in the plurality of incomplete MR K-space data matrices 302. Such reconstruction may be performed by the first AI engine 310 applying one or more weights and/or biases (e.g., as a result of having previously trained such first AI engine 310). The complete MR K-space data matrix may be of the scanned object and it may correspond to a complete MR K-space acquisition. Exemplary reconstructed complete MR K-space data matrix 312 is illustrated in FIG. 3. The reconstructed complete MR K-space data matrix 312 may be a two-dimensional MR K-space data matrix. The reconstructed complete MR K-space data matrix may be equivalent in resolution to an MR image obtained using a full sampling of K-space.

Method 100 may further include generating a reconstructed MR image matrix at block 110. The generation of the reconstructed MR image matrix may be based on the reconstructed complete K-space data matrix 312. In one embodiment, the reconstructed MR image matrix may be generated by performing the inverse Fourier transform on the reconstructed MR K-space data matrix 312. With reference to FIG. 7, image/data matrix transform generator 704 may be adapted to perform the inverse Fourier transform on the reconstructed MR K-space data matrix 312, thereby generating the reconstructed MR image matrix. The reconstructed MR image matrix may be subsequently processed for display, e.g., on a suitable monitor.

### Training the AI Engine

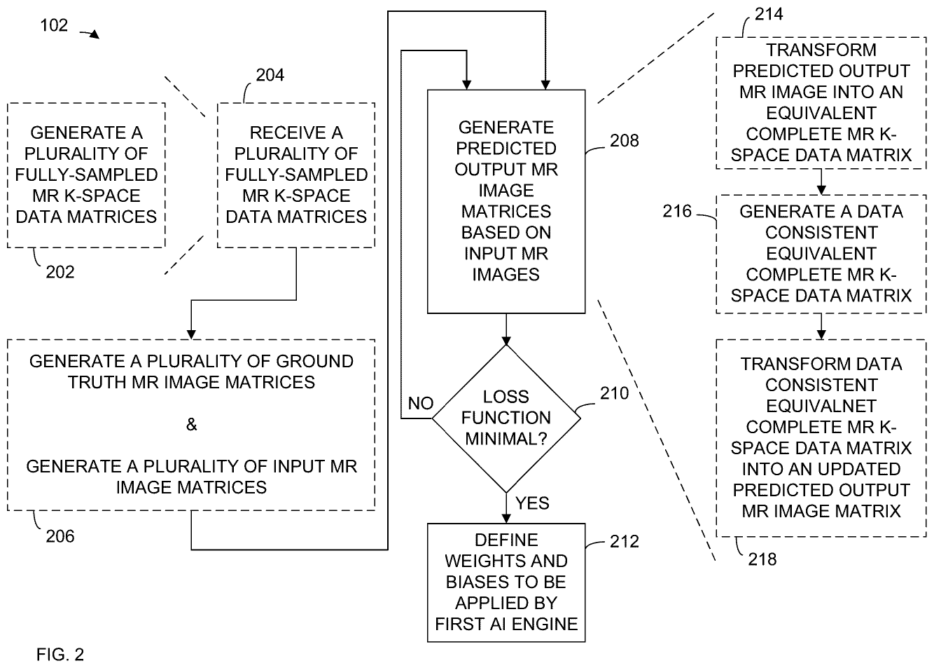

In one embodiment, the AI engine described in reference to FIG. 1 and otherwise identified as first AI engine 310 may be a first trained AI engine. Accordingly, method 100 may include block 102 where the first AI engine 310 is trained. FIGS. 2 and 4-7 depict method blocks associated with method block 102, workflows 400, 500 and 600 for training first AI engine 310, and components of system 700 adapted to train first AI engine 310. Method 102 may include block 202 where a plurality of fully-sampled MR K-space data matrices are generated. Fully-sampled MR K-space data matrices may be generated by an MR device (e.g., MR device 716) and in particular MR scanner 718, one or more fully-sampled MR scan acquisition sequence(s) 721, sampler 726 and memory 728 in a process substantially identical to the acquisition of the incomplete MR K-space data matrices 302 as described above. In one embodiment, each of the fully-sampled MR K-space data matrices are the result of an MR scan of an object obtained at the same position. For example, each of the fully-sampled MR-K space matrices may be the result of a scan of an object obtained at the same X-Y-Z position; i.e., the coordinates of the object (e.g., patient or body contours) have not changed across the scans, in each case relative to the magnetic field gradients imposed in X-Y-Z by the MR device gradient coils (not depicted).

In one embodiment, method 102 includes block 204 where a plurality of fully-sampled MR K-space data matrices are received. The plurality of fully-sampled MR K-space data matrices may be received by first AI engine 310. In another embodiment, method 102 may include block 206 where a plurality of ground truth MR image matrices and a plurality of input MR image matrices are generated. Each ground truth MR image matrix of the plurality of ground truth MR image matrices may correspond to a fully-sampled MR K-space data matrix of the plurality of fully-sampled MR K-space data matrices that may have been generated in block 202 and/or received in block 204. The plurality of ground truth MR image matrices may be generated by performing the inverse Fourier transform on the plurality of fully-sampled MR K-space data matrices. In one embodiment, first AI engine training data generator 702 includes image/data matrix transform generator 704. Image/data matrix transform generator 704 may be adapted to perform the inverse Fourier transform on the plurality of fully-sampled MR K-space data matrices, thereby generating the plurality of ground truth MR image matrices.

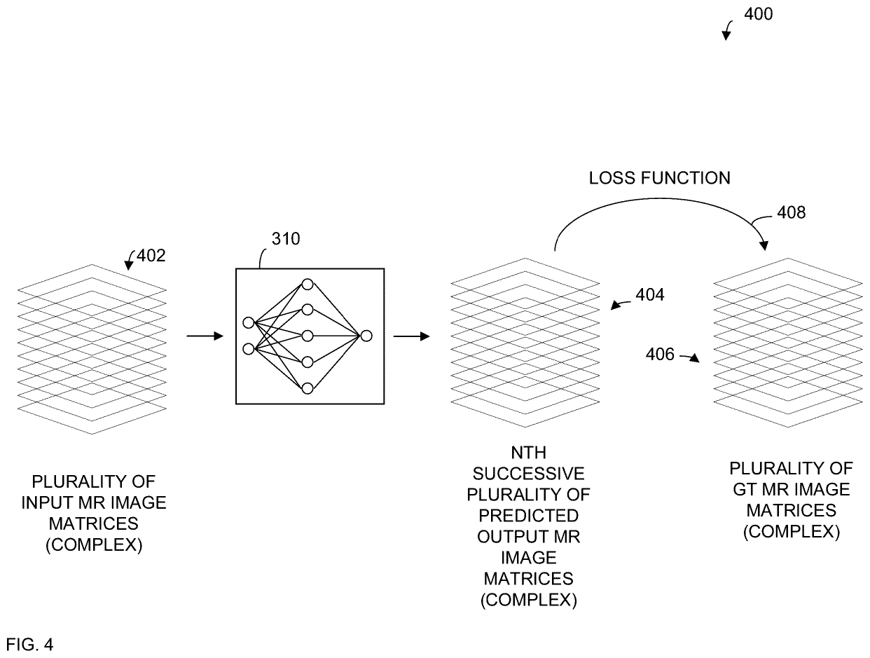

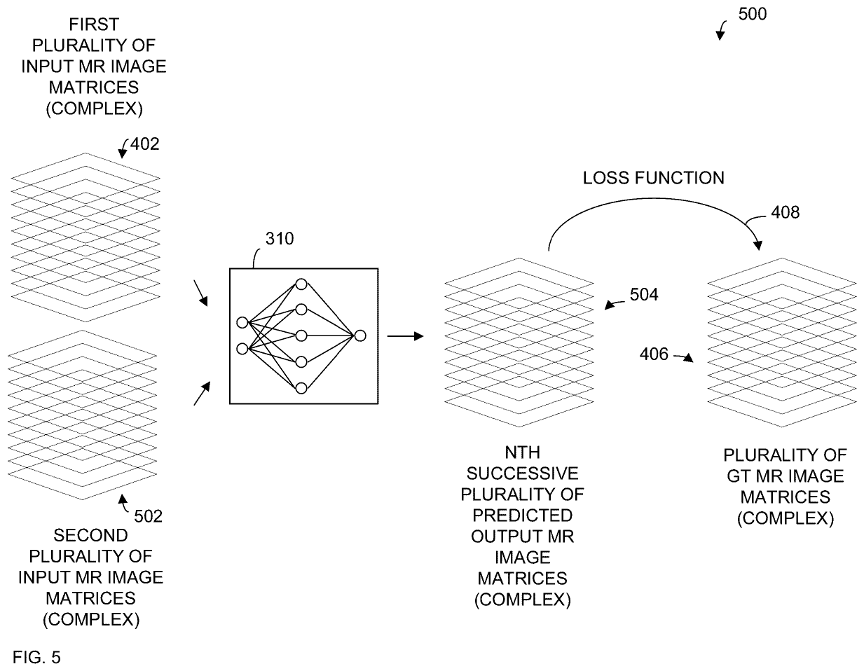

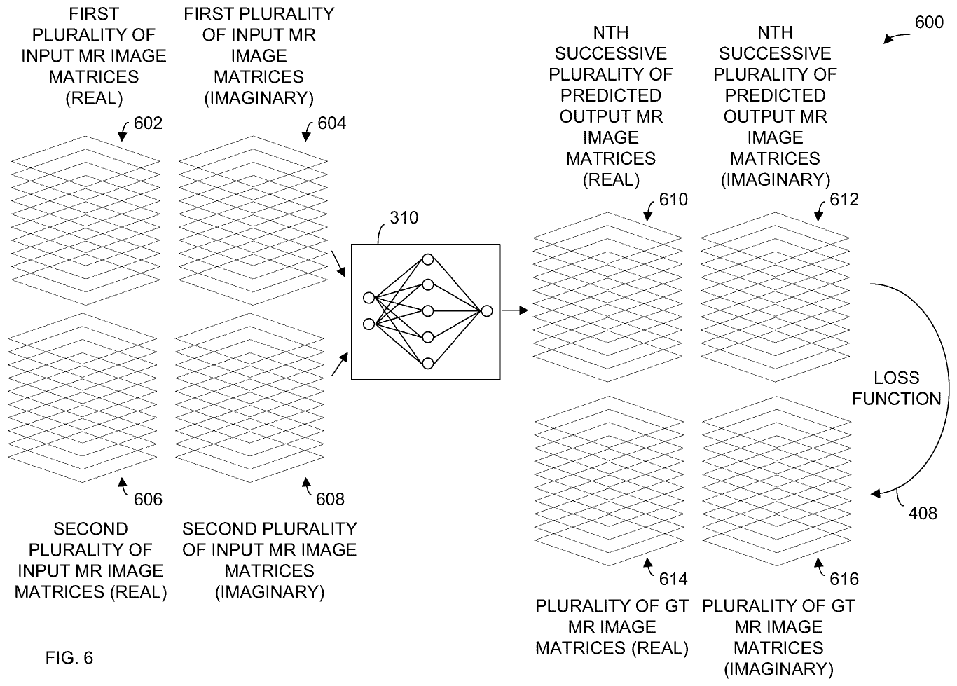

In one embodiment, each ground truth MR image matrix of the plurality of ground truth MR image matrices comprises complex values. An exemplary plurality of ground truth MR image matrices 406 is depicted in FIGS. 4-5. In other embodiments, the plurality of ground truth MR image matrices comprises a plurality of real-valued ground truth MR image matrices and a plurality of imaginary-valued ground truth MR image matrices. Exemplary pluralities of real-valued and imaginary-valued ground truth MR image matrices 614 and 616 are depicted in FIG. 6.

Returning to block 206, a plurality of input MR image matrices may be generated by down-sampling each fully-sampled MR K-space data matrix of the plurality of fully-sampled MR K-space matrices using one of the unique sampling patterns and performing the inverse Fourier transform on each of the plurality of down-sampled MR K-space data matrices, thereby generating the plurality of input MR image matrices. First AI engine training data generator 702 may including a down sampler 706 adapted to perform the above-described down-sampling, and the inverse Fourier transform may be performed by image/data matrix transform generator 704. Based on the foregoing, each input MR image matrix of the first plurality of input MR image matrices corresponds to a ground truth MR image matrix of the plurality of ground truth MR image matrices. In one embodiment, each input MR image matrix of the plurality of input MR image matrices comprise complex values. An exemplary first plurality of input MR image matrices 402 are depicted in FIG. 4.

In an embodiment, the plurality of input MR image matrices may include two pluralities of input MR image matrices, i.e., a first plurality of input MR image matrices and a second plurality of input MR image matrices. The first plurality of input MR image matrices may generated as described immediately above. That is, the first plurality of input MR image matrices may be based on a first one of the unique sampling patterns, an example of which is depicted in FIG. 5 as first plurality of input MR image matrices 402. The second plurality of input MR image matrices may be based on a second one of the unique sampling patterns and otherwise generated using the same process as described above. That is, the second plurality of input MR image matrices may be generated by down-sampling each fully-sampled MR K-space data matrix of the plurality of fully-sampled MR K-space matrices using the second one of the unique sampling patterns and performing the inverse Fourier transform on each of the plurality of down-sampled MR K-space data matrices, thereby generating the second plurality of input MR image matrices. In one embodiment, each of the first one of the unique sampling patterns and the second one of the unique sampling patterns is an unique realization of the same probability distribution function. The same components of system 700 used to generate first plurality of input MR image matrices may be used to generate second plurality of input MR image matrices. In one embodiment, each input MR image matrix of the second plurality of input MR image matrices comprises complex values. Exemplary second plurality of input MR image matrices 502 is depicted in FIG. 5.

In one embodiment, the first plurality of input MR image matrices comprises a first plurality of real-valued input MR image matrices and a first plurality of imaginary-valued input MR image matrices. Exemplary first plurality of real-valued and imaginary-valued input MR image matrices 602 and 604 are depicted in FIG. 6. In one embodiment, the second plurality of input MR image matrices comprises a second plurality of real-valued input MR image matrices and a second plurality of imaginary-valued input MR image matrices. Exemplary second plurality of real-valued and imaginary-valued input MR image matrices 606 and 608 are depicted in FIG. 6.

In one embodiment, the plurality of ground truth MR image matrices 406 and the plurality of input MR image matrices 402 may constitute the “training data” used to train the first AI engine 310, as is generally depicted in workflow 400. In an embodiment, the plurality of ground truth MR image matrices 406 and the first and second pluralities of input MR image matrices 402, 502 may constitute the “training data” used to train the first AI engine 310, as is generally depicted in workflow 500. In one embodiment, the plurality of ground truth MR image matrices 614, 616 and the first and second pluralities of input MR image matrices 602-608 may constitute the “training data” used to train the first AI engine 310, as is generally depicted in workflow 600.

Returning to method 102, first AI engine 310 may be adapted to generate predicted output MR image matrices based on the plurality of input MR image matrices at block 208. First AI engine 310 may employ gradient descent logic and/or backpropagation logic to generate predicted output MR image matrices. In one embodiment, each predicted output MR image matrix of the plurality of predicted output MR image matrices comprises complex values. The method proceeds to block 210 where it is determined whether the output of a loss function of the plurality of predicted output MR image matrices and the plurality of ground truth MR image matrices is at or below an acceptable threshold value. In one embodiment, the acceptable threshold value corresponds to a loss function output where the resolution of spatial features in each ground truth MR image matrix of the plurality of ground truth MR image matrices is substantially preserved in the corresponding predicted output MR image matrix of the plurality of predicted output MR image matrices. The acceptable threshold value can be a determined or predetermined acceptable minimal value. In one embodiment, the loss function is a root mean square function. An exemplary loss function is expressed as is set forth in Equation 1. Other functions may be employed at block 210.

$$Loss Function Output = \sqrt{{\sum }_{x = i}^{X} {( real {PO}_{x} - real {GT}_{x} )}^{2} + {( imaginary {PO}_{x} - imaginary {GT}_{x} )}^{2}} ; where : \qquad ( Equation 1 )$$

$$“ real {PO}_{x} ” is the xth predicted output MR image matrix ( real ) for a given plurality of X predicted output MR image matrices ( real ) ;$$

$$“ real {GT}_{x} ” is the xth ground truth MR i mage matrix ( real ) of the plurality of X GT MR image matrices ( real ) ;$$

$$“ imaginary {PO}_{x} ” is the xth predicted output MR image matrix ( imaginary ) for a given plurality of X predicted output MR image matrices ( imaginary ) ;$$

$$“ imaginary {GT}_{x} ” is the xth ground truth MR image matrix ( imaginary ) of the plurality of X GT MR image matrices ( imaginary ) .$$

If the output of the loss function is less than the acceptable threshold value, then the method proceeds to block 212 where weights and biases are defined. The weights and biases may be defined based on the parameters used by the first AI engine 310 to generate the plurality of predicted output MR image matrices. Such weights and biases may be used by the first AI engine 310 to reconstruct the complete MR K-space data matrix 312 as was described above.

If, however, the output of the of the loss function is not less than the acceptable threshold value, then the method returns to block 208 where a successive plurality of predicted output MR image matrices 504 is determined and a determination is made as to whether the output of a loss function is at or less than the acceptable threshold value. The process continues until the nth successive plurality of predicted output MR image matrices 504 results in a satisfactory loss function 408 output (i.e., the output of loss function is at or below an acceptable threshold value).

With reference to FIGS. 4-5 and workflows 400 and 500, block 210 compares the nth successive plurality of predicted output MR image matrices 404 or 504 to the plurality of ground truth MR image matrices 406 using a loss function 408. And with reference to FIG. 6 and workflow 600, block 210 compares the nth successive real-valued and imaginary-valued plurality of predicted output MR image matrices 610, 612 to the real-valued and imaginary-valued ground truth MR image matrices 614, 616 using a loss function 408.

With reference to FIG. 7, in one embodiment, first AI engine 310 may include gradient descent logic 708 and/or backpropagation logic 710, and loss function logic 712 to implement method blocks 208 and 210.

In an embodiment, block 208 includes, for each predicted output MR image matrix in each successive plurality of predicted MR image matrix, method blocks 214-218. In method block 214, a predicted output MR image matrix is transformed into an equivalent complete MR K-space data matrix. In one embodiment, method block can be performed by image/data matrix transform generator 704 by, for example, performing the Fourier transform on the predicted output MR image matrix. In block 216, a data consistent equivalent complete MR K-space data matrix may be generated. In one embodiment, the data consistent equivalent complete MR K-space data matrix is generated by enforcing a data consistency constraint by overriding values in the equivalent complete MR K-space data matrix with corresponding values in the corresponding fully-sampled MR K-space data matrix of the plurality of fully-sampled MR K-space data matrices. Block 216 may be performed by data consistency logic 713. In block 218, the data consistent equivalent complete K-space data matrix is transformed into an updated predicted output MR image matrix. In one embodiment, the transformation may be performed by applying the inverse Fourier transform on the data consistent equivalent complete MR K-space data matrix. Block 218 may be performed by image/data matrix transform generator 704. The plurality of updated predicted output MR image matrices may be input into the loss function at block 210.

System 700 may include second AI engine 714 that is adapted to select the unique sampling pattern for purpose of training first AI engine 310. The second AI engine 714 may be an AI engine trained by supervised learning algorithm. In one embodiment, first AI engine 310 and second AI engine 714 may be configured as a generative adversarial network.

The technology and techniques described herein overcomes the pitfalls of the prior art and in particular the use of sparse-sampling/compressed sensing MRI. The technology and techniques retain the benefits of sparse-sampling/compressed sensing MRI, including accelerated MRI acquisitions and shortened scan times, while improving MR image quality. The result is a single high-quality image that is equivalent or substantially equivalent in resolution to an MR image resultant from a full sampling of K-space, but with less ghosting and/or artifacts such as motion artifacts. The technology and techniques described herein results in improved patient comfort. By using an AI engine for the reconstructions, the AI engine can learn, via sufficient training, how to combine the different spatial features from multiple input scans in an optimal way. The technology and techniques described herein can be applied to any MRI system, including but not limited to MRI systems employing super-conducting magnets and permanent magnets, and to both 2D and 3D MRI. In 2D MRI, one dimension may be sparsely sampled and in 3D MRI two dimensions may be sparsely sampled (e.g., randomized down-sampling on both Y and Z phase encoded dimensions).

As used herein, the terms “module,” “logic,” “engine” and its and their components may refer to any single or collection of circuit(s), integrated circuit(s), hardware processor(s), processing device(s), transistor(s), non-transitory memory(s), storage devices(s), non-transitory computer readable medium(s), combination logic circuit(s), or any combination of the above that is capable of providing a desired operation(s) or function(s). For example, a “module”, “logic” or “engine” may take the form of a hardware processor executing instructions from one or more non-transitory memories, storage devices, or non-transitory computer readable media, or a dedicated integrated circuit. “Non-transitory memory,” “non-transitory computer-readable media,” and “storage device” may refer to any suitable internal or external non-transitory, volatile or non-volatile, memory device, memory chip(s), or storage device or chip(s) such as, but not limited to system memory, frame buffer memory, flash memory, random access memory (RAM), read only memory (ROM), a register, a latch, or any combination of the above. A “hardware processor” may refer to one or more dedicated or non-dedicated: hardware micro-processors, hardware micro-controllers, hardware sequencers, hardware micro-sequencers, digital signal hardware processors, hardware processing engines, hardware accelerators, applications specific circuits (ASICs), hardware state machines, programmable logic arrays, any integrated circuit(s), discreet circuit(s), etc. that is/are capable of processing data or information, or any suitable combination(s) thereof. A “processing device” may refer to any number of physical devices that is/are capable of processing (e.g., performing a variety of operations on) information (e.g., information in the form of binary data or carried/represented by any suitable media signal, etc.). For example, a processing device may be a hardware processor capable of executing executable instructions, a desktop computer, a laptop computer, a mobile device, a hand-held device, a server (e.g., a file server, a web server, a program server, or any other server), any other computer, etc. or any combination of the above. An example of a processing device may be a device that includes one or more integrated circuits comprising transistors that are programmed or configured to perform a particular task. “Executable instructions” may refer to software, firmware, programs, instructions or any other suitable instructions or commands capable of being processed by a suitable hardware processor. The terms “adapted to” and “configured to” mean physically adapted and/or configured to.

While illustrative embodiments have been described herein, the scope thereof includes any and all embodiments having equivalent elements, modifications, omissions, combinations (e.g., of aspects across various embodiments), adaptations and/or alterations as would be appreciated by those in the art based on the present disclosure. For example, the number and orientation of components shown in the exemplary systems may be modified.

Those skilled in the art will appreciate that the method blocks need not necessarily be performed in the order in which they are depicted in the figures or described herein. For example, the order of the acts may be rearranged; some acts may be performed in parallel; shown acts may be omitted, or other acts may be included; a shown act may be divided into sub acts, or multiple shown acts may be combined into a single act, etc. Similarly, those skilled in the art will appreciate that one or more components depicted in functional block diagrams may be omitted without deviating from the scope of the disclosure. In particular and without limiting the immediately foregoing sentence, those components denoted in dashed lines may be omitted in one or all embodiments.

It will be appreciated by those skilled in the art that the above-described facility may be straightforwardly adapted or extended in various ways. While the foregoing description makes reference to particular embodiments, the scope of the invention is defined solely by the claims that follow and the elements recited therein.

What is claimed is:

1. A method comprising:
receiving, by a first artificial intelligence (AI) engine, a plurality of incomplete magnetic resonance (MR) K-space data matrices of an object scanned by an MR device, wherein each of the incomplete MR K-space data matrices comprises complex values and is the result of a corresponding scan of the object by the MR device using a sparse-sampled MR scan acquisition sequence wherein each said sparse-sampled MR scan acquisition sequence employs a unique sampling pattern; and
reconstructing, by the first AI engine, a complete MR K-space data matrix of the scanned object corresponding to a complete MR K-space acquisition, wherein the reconstruction is based on the data in the plurality of incomplete MR K-space data matrices.

2. The method of claim 1, wherein each unique sampling pattern is unique across the phase-encoded dimension of K-space, such that the plurality of incomplete MR K-space data matrices contains variations in sampled spatial information due to a difference in the unique sampling patterns.

3. The method of claim 1, the method further comprising generating, by the first AI engine, a reconstructed MR image matrix based on the reconstructed complete MR K-space data matrix by performing the inverse Fourier transform on the reconstructed complete MR K-space data matrix.

4. The method of claim 1, further comprising training the first AI engine using a first AI engine training data generator configured to implement a gradient descent algorithm and a backpropagation algorithm with training data comprising a first plurality of input MR image matrices and a plurality of ground truth MR image matrices, wherein:
each ground truth MR image matrix of the plurality of ground truth MR image matrices corresponds to a fully-sampled MR K-space data matrix,
each input MR image matrix of the first plurality of input MR image matrices is an image matrix corresponding to a down-sampled version of a MR K-space data matrix corresponding to one ground truth MR image matrix of the plurality of ground truth MR image matrices, the down-sampling having been performed using a first one of the unique sampling patterns, and
the gradient descent algorithm and the backpropagation algorithm iteratively generates successive pluralities of predicted output MR image matrices based on the first plurality of input MR image matrices, until the output of a loss function of the nth successive plurality of predicted output MR image matrices and the plurality of ground truth MR image matrices is below a value, thereby defining weights and biases to be applied by the first AI engine.

5. The method of claim 4, wherein the training data comprises a second plurality of input MR image matrices, each input MR image of the second plurality of input MR image matrices is an image matrix corresponding to a down-sampled version of a MR K-space data matrix corresponding to one ground truth MR image matrix of the plurality of ground truth MRI image matrices, the down-sampling having been performed using a second one of the unique sampling patterns, where the second one of the unique sampling patterns is different than the first one of the unique sampling patterns.

6. The method of claim 5, wherein the gradient descent algorithm and the backpropagation algorithm iteratively generates the successive pluralities of predicted output MR image matrices based on the first plurality of input MR image matrices and the second plurality of input MR images.

7. The method of claim 6, wherein each predicted output MR image matrix is based on a corresponding input MR image matrix from the first plurality of input MR image matrices and a corresponding input MR image matrix from the second plurality of input MR image matrices.

8. The method of claim 6, wherein:
the first plurality of input MR image matrices comprises a first plurality of real-valued input MR image matrices and a first plurality of imaginary-valued input MR image matrices,
the second plurality of input MR image matrices comprises a second plurality of real-valued input MR image matrices and a second plurality of imaginary-valued input MR image matrices,
the plurality of ground truth MR image matrices comprises a plurality of real-valued ground truth MR image matrices and a plurality of imaginary-valued ground truth MR image matrices, and
the plurality of predicted output MR image matrices comprises a plurality of real-valued predicted output MR image matrices and a plurality of imaginary-valued predicted output MR image matrices.

9. The method of claim 4, wherein the resolution of spatial features in each ground truth MR image matrix of the plurality of ground truth MR image matrices is substantially preserved in the corresponding predicted output MR image matrix of the nth successive plurality of predicted output MR image matrices.

10. The method of claim 1, wherein the plurality of incomplete MR K-space scans are acquired using a static MR acquisition technique.

11. The method of claim 1, wherein receiving, by the first AI engine, the plurality of incomplete MR K-space data matrices of an object scanned by an MR device comprises receiving the plurality of incomplete MR K-space scans as multi-channel inputs.

12. A system comprising a first artificial intelligence (AI) engine configured to:
receive a plurality of incomplete magnetic resonance (MR) K-space data matrices of an object scanned by an MR device, wherein each of the incomplete MR K-space data matrices comprises complex values and is the result of a corresponding scan of the object by the MR device using a sparse-sampled MR scan acquisition sequence wherein each said sparse-sampled MR scan acquisition sequence employs a unique sampling pattern; and
reconstruct a complete MR K-space data matrix of the scanned object corresponding to a complete MR K-space acquisition, wherein the reconstruction is based on the data in the plurality of incomplete MR K-space data matrices.

13. The system of claim 12, wherein each unique sampling pattern is unique across the phase-encoded dimension of K-space, such that the plurality of incomplete MR K-space data matrices contains variations in sampled spatial information due to a difference in the unique sampling patterns.

14. The system of claim 13, wherein each unique sampling pattern is a unique realization of the same probability distribution function.

15. The system of claim 14, wherein the probability distribution function is one of: a Gaussian probability distribution function and a Poisson probability distribution function.

16. The system of claim 12, the first AI engine is further configured to generate a reconstructed MR image matrix based on the reconstructed complete MR K-space data matrix.

17. The system of claim 16, where the first AI engine is configured to generate the reconstructed MR image matrix by performing the inverse Fourier transform on the reconstructed complete MR K-space data matrix.

18. The system of claim 12, further comprising a first AI engine training data generator configured to train the first AI engine using a gradient descent algorithm and a backpropagation algorithm with training data comprising a first plurality of input MR image matrices and a plurality of ground truth MR image matrices, wherein:
each ground truth MR image matrix of the plurality of ground truth MR image matrices corresponds to a fully-sampled MR K-space data matrix,
each input MR image matrix of the first plurality of input MR image matrices is an image matrix corresponding to a down-sampled version of a MR K-space data matrix corresponding to one ground truth MR image matrix of the plurality of ground truth MR image matrices, the down-sampling having been performed using a first one of the unique sampling patterns, and
the gradient descent algorithm and the backpropagation algorithm iteratively generates successive pluralities of predicted output MR image matrices based on the first plurality of input MR image matrices, until the output of a loss function of the nth successive plurality of predicted output MR image matrices and the plurality of ground truth MR image matrices is below a value, thereby defining weights and biases to be applied by the first AI engine.

19. The system of claim 18, wherein the training data comprises a second plurality of input MR image matrices, each input MR image of the second plurality of input MR image matrices is an image matrix corresponding to a down-sampled version of a MR K-space data matrix corresponding to one ground truth MR image matrix of the plurality of ground truth MRI image matrices, the down-sampling having been performed using a second one of the unique sampling patterns, where the second one of the unique sampling patterns is different than the first one of the unique sampling patterns.

20. The system of claim 19, wherein the gradient descent algorithm and the backpropagation algorithm iteratively generates the successive pluralities of predicted output MR image matrices based on the first plurality of input MR image matrices and the second plurality of input MR images.

21. The system of claim 20, wherein each predicted output MR image matrix is based on a corresponding input MR image matrix from the first plurality of input MR image matrices and a corresponding input MR image matrix from the second plurality of input MR image matrices.

22. The system of claim 20, wherein:
each input MR image matrix of the first plurality of input MR image matrices comprises complex values,
each input MR image matrix of the second plurality of input MR image matrices comprises complex values,
each ground truth MR image matrix of the plurality of ground truth MR image matrices comprises complex values, and
each predicted output MR image matrix of the plurality of predicted output MR image matrices comprises complex values.

23. The system of claim 20, wherein:
the first plurality of input MR image matrices comprises a first plurality of real-valued input MR image matrices and a first plurality of imaginary-valued input MR image matrices,
the second plurality of input MR image matrices comprises a second plurality of real-valued input MR image matrices and a second plurality of imaginary-valued input MR image matrices,
the plurality of ground truth MR image matrices comprises a plurality of real-valued ground truth MR image matrices and a plurality of imaginary-valued ground truth MR image matrices, and
the plurality of predicted output MR image matrices comprises a plurality of real-valued predicted output MR image matrices and a plurality of imaginary-valued predicted output MR image matrices.

24. The system of claim 18, wherein the first AI engine training data generator is further configured to:
generate the plurality of ground truth MR image matrices by performing the inverse Fourier transform on a plurality of fully-sampled MR K-space data matrices; and
generate the first plurality of input MR image matrices by:
down-sampling each fully-sampled MR K-space data matrix of the plurality of fully-sampled MR K-space data matrices using the unique sampling pattern; and
performing the inverse Fourier transform on each of the plurality of down-sampled MR K-space data matrices.

25. The system of claim 18, wherein each fully-sampled MR K-space data matrix is the result of an MR scan of an object obtained at the same position.

26. The system of claim 18, wherein each unique sampling pattern is a unique realization of the same probability distribution function.

27. The system of claim 18, wherein the loss function is a root mean square function.

28. The system of claim 18, wherein the resolution of spatial features in each ground truth MR image matrix of the plurality of ground truth MR image matrices is substantially preserved in the corresponding predicted output MR image matrix of the nth successive plurality of predicted output MR image matrices.

29. The system of claim 18, wherein for each predicted output MR image matrix, the first AI engine is further configured to:
transform said predicted output MR image matrix into an equivalent complete MR K-space data matrix;
enforce a data consistency constraint by overriding values in said equivalent complete MR K-space data matrix with the corresponding values in the corresponding fully-sampled MR K-space data matrix, thereby generating a data consistent equivalent complete MR K-space data matrix; and
transform said data consistent equivalent complete MR K-space data matrix into an updated predicted output MR image matrix.

30. The system of claim 29, wherein the first AI engine is further configured to:
transform said predicted output MR image into the equivalent complete MR K-space data matrix comprises performing the Fourier transform on the predicted output MR image; and
transform said data consistent equivalent complete MR K-space data matrix into an updated predicted output MR image matrix comprises performing the inverse Fourier transform on the data consistent equivalent complete MR K-space data matrix.

31. The system of claim 12, further comprising an MR device configured to generate the plurality of incomplete MR K-space data matrices by:
implementing on the MR device, said sparse-sampled MR scan acquisition sequence, thereby generating MR signal data at a receiver coil of the MR device;
sampling the MR signal data; and
storing the sampled MR signal data as a MR K-space data matrix, thereby generating one of the plurality of incomplete MR K-space data matrices.

32. The system of claim 12, wherein each of the plurality of incomplete MR K-space data matrices and the complete MR K-space data matrix is a two-dimensional MR K-space data matrix.

33. The system of claim 12, wherein the first AI engine is a convolutional neural network based on a first deep learning model.

34. The system of claim 12, further comprising a second AI engine configured to select the unique sampling pattern for each sparse-sampled MR scan acquisition sequence.

35. The system of claim 12, further comprising a second AI engine configured to select each unique sampling pattern.

36. The system of claim 34, wherein the second AI engine was configured using a supervised learning algorithm.

37. The system of claim 34, wherein the first and second AI engines are configured as a generative adversarial network.

38. The system of claim 12, wherein the plurality of incomplete MR K-space scans are acquired using a static MR acquisition technique.

39. The system of claim 12, wherein the plurality of incomplete MR K-space data matrices comprise:
two incomplete MR K-space data matrices for T1-weighted MR imaging;
two incomplete MR K-space data matrices for T2-weighted MR imaging; and
three incomplete MR K-space data matrices for diffusion-weighted MR imaging.

40. The system of claim 12, the first AI engine is configured to receive the plurality of incomplete MR K-space data matrices of an object scanned by an MR device by receiving the plurality of incomplete MR K-space scans as multi-channel inputs.
